(19) United States
(12) Patent Application Publication
(10) Pub. No.: US 2005/0253524 A1
(43) Pub. Date: Nov. 17, 2005

(54) Method for manufacturing an organic electroluminescent element, system for manufacturing an organic electroluminescent element, and electronic equipment

(75) Inventor: Kohei Ishida, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/098,464

(22) Filed: Apr. 5, 2005

(30) Foreign Application Priority Data
May 17, 2004 (JP) 2004-146439

(51) Int. Cl. H01J 61/30

(52) U.S. Cl. 313/634; 427/66

(57) ABSTRACT

Aspects of the invention can provide a method for manufacturing an organic EL element, a system for manufacturing an organic electroluminescent (EL) element, and electronic equipment that are capable of moving a tape-like substrate by a reel-to-reel method so as to produce an organic EL element with the droplet discharge. The method for manufacturing an organic EL element provided on a tape-like substrate can include providing the tape-like substrate 11 both ends of which are reeled in as a reel-to-reel substrate, and providing a hole injection/transport layer for applying a liquid substance containing a component of the hole injection/transport layer of the organic EL element on the reel-to-reel substrate by at least using a droplet discharge method that discharges and applies the liquid substance as a droplet.

### BACKGROUND

Aspects of the invention can relate to a method for manufacturing an organic electroluminescent (EL) element, a system for manufacturing an organic EL element, and electronic equipment.

To manufacture wiring used for electronic circuits, integrated circuits, or the like, lithography is employed, for example, which requires a vacuum apparatus and other heavy equipment and complicated processing. Having a low efficiency of several percent in the use of materials, the lithography wastes a large part of materials and requires high manufacturing cost. Therefore, to replace the lithography, methods for patterning a liquid substance containing a functional material directly on a base material by ink jetting (i.e., droplet discharge) have been developed. For example, a related art method has been proposed that applies a liquid substance in which conductive particles are dispersed directly on a substrate in a pattern by the droplet discharge, and then performs heat treatment and laser irradiation so as to convert the pattern into a conductive film pattern. See, for example, U.S. Pat. No. 5,132,248.

Also, a related art method for manufacturing a display or device employing the droplet discharge has been devised that flexibly copes with the kind of manufacturing steps to which the method is applied. More specifically, a relative velocity V of a droplet discharge head to a substrate, a droplet discharge period T, and a droplet diameter D that has landed and spread on the substrate are controlled so as to satisfy the formula: VT<D. A droplet is discharged on the substrate under optimum conditions depending on the kind of manufacturing steps to which the method is applied. See, for example, Japanese Unexamined Patent Publication No. 2003-280535.

A typical arrangement of an organic EL device used for a display, for example, includes an organic luminescent layer sandwiched between an anode and a cathode. An arrangement can include a hole injection/transport layer provided between an anode and an organic luminescent layer for injecting and transporting holes from the anode to the organic luminescent layer. See, for example, Japanese Unexamined Patent Publication No. 2001-338755.

### SUMMARY

According to the related art manufacturing methods described above, a plate-like substrate is processed into a product substrate through many steps. In order to go through these steps, the substrate needs to be moved from one place for one step (device) to another place for another step. Therefore, the related art manufacturing methods involve the problem of requiring a great amount of labor and mechanism for moving and aligning the substrate, which can increase cost for manufacturing organic EL devices. In other words, the related art manufacturing methods needs to arrange a surface treatment device, droplet discharge device, and drying device, and move a substrate on which an organic EL device is provided from one device to another with accurate alignment. Accordingly, they require a great amount of labor and complicated moving mechanism of a robot, for example.

Taking this into account, the aspects of invention aims to provide a method for manufacturing an organic EL element, a system for manufacturing an organic EL element, and electronic equipment that are capable of efficiently mass producing organic EL elements.

The aspects of invention also aims to provide a method for manufacturing an organic EL element, a system for manufacturing an organic EL element, and electronic equipment that are capable of moving a tape-like substrate by a so-called reel-to-reel method so as to produce an organic EL element with a droplet discharge method.

A method for manufacturing an organic EL element provided on a tape-like substrate according to an aspect of the invention can include providing the tape-like substrate, both ends of which are reeled in as a reel-to-reel substrate and providing a hole injection/transport layer for applying a liquid substance containing a component of the hole injection/transport layer of the organic electroluminescent element on the reel-to-reel substrate by at least using a droplet discharge method that discharges and applies the liquid substance as a droplet.

According to this aspect of the invention, the hole injection/transport layer included in the organic EL element is provided by droplet discharge on the reel-to-reel substrate (tape-like substrate). Here, a plurality of areas divided in the longitudinal direction may be formed on one reel-to-reel substrate. Each of the areas may have an organic EL device. Accordingly, the hole injection/transport layer may be provided by droplet discharge in each area while moving the reel-to-reel substrate in its longitudinal direction, for example, according to this aspect of the present invention. Therefore, it is possible to manufacture hole injection/transport layers of a large number of organic EL devices efficiently and promptly.

A method for manufacturing an organic EL element provided on a tape-like substrate according to another aspect of the invention can include providing the tape-like substrate both ends of which are reeled in as a reel-to-reel substrate, and providing a luminescent layer for applying a liquid substance containing a component of the luminescent layer of the organic electroluminescent element on the reel-to-reel substrate by at least using a droplet discharge method that discharges and applies the liquid substance as a droplet.

According to this aspect of the invention, the luminescent layer included in the organic EL element can be provided by droplet discharge on the reel-to-reel substrate. Accordingly, the luminescent layer is provided easily and continuously in a plurality of areas arranged in the longitudinal direction of the reel-to-reel substrate, for example, according to this aspect of the present invention. Therefore, it is possible to manufacture luminescent layers of a large number of organic EL devices efficiently and promptly.

In the method for manufacturing an organic electroluminescent element, it is preferable that at least providing the hole injection/transport layer and providing the luminescent layer are performed during a period from the reel-to-reel substrate is pulled out to the reel-to-reel substrate is reeled in, and providing the hole injection/transport layer is followed by providing the luminescent layer. Accordingly, the hole injection/transport layer is provided on the reel-to-reel substrate by droplet discharge, and then the luminescent layer is provided in an upper layer of the hole injection/transport layer by droplet discharge. Accordingly, a multilayered structure composed of the hole injection/transport layer and the luminescent layer is provided easily and continuously in a plurality of areas arranged in the longitudinal direction of the reel-to-reel substrate, for example, according to this aspect of the present invention. Therefore, it is possible to manufacture the hole injection/transport layer and the luminescent layers of a large number of organic EL devices efficiently and promptly.

In the method for manufacturing an organic electroluminescent element, it is preferable that at least providing the hole injection/transport layer and providing the luminescent layer are performed during a period from the reel-to-reel substrate is pulled out to the reel-to-reel substrate is reeled in, and providing the hole injection/transport layer and providing the luminescent layer are performed for the same reel-to-reel substrate in an overlapping time period. Accordingly, for example, while a first droplet discharge device applies a liquid substance for forming the hole injection/transport layer in an area on the reel-to-reel substrate, a second droplet discharge device may apply a liquid substance for forming the luminescent layer in another area (e.g., on the hole injection/transport layer) on the reel-to-reel substrate. Therefore, a multilayered structure composed of the hole injection/transport layer and the luminescent layer is provided like in a conveyor system. Therefore, it is possible to manufacture hole injection/transport and luminescent layers of a large number of organic EL devices efficiently and promptly.

The method for manufacturing an organic electroluminescent element preferably includes hardening a liquid substance applied on the reel-to-reel substrate by at least one of providing the hole injection/transport layer and providing the luminescent layer. Accordingly, a liquid substance containing the component of the hole injection/transport layer or the luminescent layer applied on the reel-to-reel substrate is hardened. On the hardened thin film, a liquid substance containing the component of the hole injection/transport layer or the luminescent layer may be applied. Therefore, it can be possible to provide a multilayered structure composed of the hole injection/transport layer and the luminescent layer easily and continuously on the reel-to-reel substrate, and mass produce organic EL devices efficiently and promptly.

Furthermore, in the method for manufacturing an organic electroluminescent element, it is preferable that hardening is performed between providing the hole injection/transport layer and providing the luminescent layer. Accordingly, it is possible to harden a liquid substance applied on the reel-to-reel substrate while providing the hole injection/transport layer, and apply a liquid substance on the hardened thin film while providing the luminescent layer. This makes it possible to perform providing the hole injection/transport layer and providing the luminescent layer at an extremely short time interval for an area on the reel-to-reel substrate. Therefore, it is possible to mass produce organic EL devices efficiently and promptly.

The method for manufacturing an organic electroluminescent element preferably can include providing a drive element (thin-film transistor, TFT) to a base substrate that is other than the tape-like substrate, and joining the base substrate and one of the tape-like substrate and a substrate included in an organic electroluminescent device so as to transfer the drive element to one of the tape-like substrate and the substrate included in the organic electroluminescent device.

Accordingly, the TFT is provided to a base substrate for example, and then the base substrate is joined to the tape-like substrate so as to transfer the TFT to the tape-like substrate. If the tape-like substrate is made of a film, the TFT cannot be directly provided on the film. Here, it is possible to provide the TFT easily on the tape-like substrate made of a film, and to mass produce active organic EL devices having the TFT economically.

Also, an organic EL device may be manufactured by providing a wiring substrate aside from the tape-like substrate, joining the wiring substrate and the base substrate so as to transfer the TFT to the wiring substrate, and joining the wiring substrate and the tape-like substrate on which an organic EL element is provided.

This way fewer processes are required after providing or transferring the drive element, such as TFT, for a drive circuit provided on the wiring substrate, and thereby substantially reducing the possibility of damaging the drive element in the manufacturing process. Also, since the electro-optical part (tape-like substrate) and the drive circuit (wiring substrate) are manufactured in separate steps, the yield can be increased. It is also possible to provide the electro-optical part (tape-like substrate) and the drive circuit (wiring substrate) that are manufactured by different plants or manufacturers to join the two substrates together, which is highly advantageous in reducing manufacturing costs. Also, it is possible to manufacture a wide-screen electro-optical device with a comparatively low investment in plant and equipment. Therefore, it is possible to mass produce organic EL devices more efficiently and promptly.

A system for manufacturing an organic electroluminescent element according to a yet another aspect of the invention includes: a first reel around which a tape-like substrate is wound, a second reel for reeling the tape-like substrate pulled out from the first reel, a first droplet discharge device including a first discharge head for discharging a liquid substance containing a component of a hole injection/transport layer of the organic electroluminescent element as a droplet on the tape-like substrate pulled out from the first reel, a second droplet discharge device including a second discharge head for discharging a liquid substance containing a component of a luminescent layer of the organic electroluminescent element as a droplet on the tape-like substrate pulled out from the first reel, a first head moving mechanism for moving the first discharge head relative to the tape-like substrate pulled out from the first reel, and a second head moving mechanism for moving the second discharge head relative to the tape-like substrate pulled out from the first reel.

According to this aspect of the invention, for example, the first head moving mechanism moves the first discharge head relative to a desired area on the tape-like substrate so as to discharge a liquid substance containing the component of the hole injection/transport layer as a droplet. Also, the second head moving mechanism moves the second discharge head relative to a desired area on the tape-like substrate so as to discharge a liquid substance containing the component of the luminescent layer as a droplet. After forming patterns for the hole injection/transport layer and the luminescent layer in one desired area, thin-film patterns for the hole injection/transport layer and the luminescent layer can be readily formed in another desired area by moving the tape-like substrate in its longitudinal direction. Here, one desired area may correspond to one organic EL device. Accordingly, it is possible to provide an organic EL device easily and promptly in each desired area on the tape-like substrate. It is also possible to efficiently mass produce organic EL devices.

In the system for manufacturing an organic electroluminescent element, it is preferable that the first discharge head and the second discharge head are disposed near the tape-like substrate pulled out from the first reel, the first discharge head is placed closer to the first reel than the second discharge head, and a drying device for hardening a liquid substance applied on the reel-to-reel substrate is disposed between the first discharge head and the second discharge head. Accordingly, the first discharge head applies a liquid substance containing the component of the hole injection/transport layer to a desired area on the tape-like substrate, and the liquid substance is then hardened by the drying device. On the hardened thin film, a liquid substance containing the component of the luminescent layer may be applied by the second discharge head. Therefore, a multilayered structure composed of the hole injection/transport layer and the luminescent layer is provided to a desired area on the tape-like substrate more promptly.

Electronic equipment according to a further aspect of the invention is manufactured by using any of the above-described methods for manufacturing an organic EL element or any of the above-described systems for manufacturing an organic EL element. This aspect of the invention provides electronic equipment including an organic EL device that is formed by dividing the tape-like substrate (reel-to-reel substrate) into desired areas. Therefore, it is possible to provide the electronic equipment including the organic EL device economically.

The electronic equipment preferably can include a passive organic EL device manufactured by using any of the above-described methods for manufacturing an organic EL element or any of the above-described systems for manufacturing an organic EL element. Accordingly, it can be possible to provide the electronic equipment including the passive organic EL device economically.

The electronic equipment preferably can include an active organic EL device manufactured by using any of the above-described methods for manufacturing an organic EL element or any of the above-described systems for manufacturing an organic EL element. Accordingly, it can be possible to provide the electronic equipment including the active organic EL device economically.

### BRIEF DESCRIPTION OF THE DRAWINGS

The invention will be described with reference to the accompanying drawings, wherein like numerals reference like elements, and wherein:

FIG. 1 is a schematic view illustrating a passive organic EL device according to a first embodiment of the present invention;

FIG. 2 is a schematic view illustrating a method for manufacturing the passive organic EL element;

FIG. 3 is a perspective view showing a droplet discharge device used in the manufacturing method;

FIGS. 4A and 4B show an inkjet head included in the droplet discharge device;

FIG. 5 is a bottom view of the inkjet head;

FIG. 6 is a partial plan view showing the arrangement etc. of flushing areas included in the droplet discharge device;

FIG. 7 is a sectional view showing an active organic EL device according to a second embodiment of the invention;

FIG. 8 is a side view of the active organic EL device seen from the direction A;

FIG. 9 is a schematic view showing a step for manufacturing the active organic EL device,

FIG. 10 is a schematic view showing a step for manufacturing the active organic EL device;

FIG. 11 is a schematic view showing a step for manufacturing the active organic EL device;

FIG. 12 is a schematic view showing a step for manufacturing the active organic EL device;

FIG. 13 is a schematic view showing a step for manufacturing the active organic EL device;

FIG. 14 is a schematic view showing a step for manufacturing the active organic EL device; and

FIGS. 15A to 15C are perspective views showing embodiments of electronic equipment according to the invention.

### DETAILED DESCRIPTION OF EMBODIMENTS

A method for manufacturing an organic EL element and a system for manufacturing an organic EL element according to exemplary embodiments of the invention will be described with reference to the accompanying drawings. A method for manufacturing an organic EL element according to one exemplary embodiment of the invention employs a system for manufacturing an organic EL element according to exemplary embodiments of the invention. An active or passive organic EL device provided on a tape-like substrate serving as a reel-to-reel substrate will be described as an example in the exemplary embodiments below. A passive organic EL device has a plurality of electrodes simply extending in rows and columns and produces images by selecting certain intersections to emit light, while an active organic EL device is provided with an active device such as a field-effect transistor (FET) and a charge storage capacitor for each pixel.

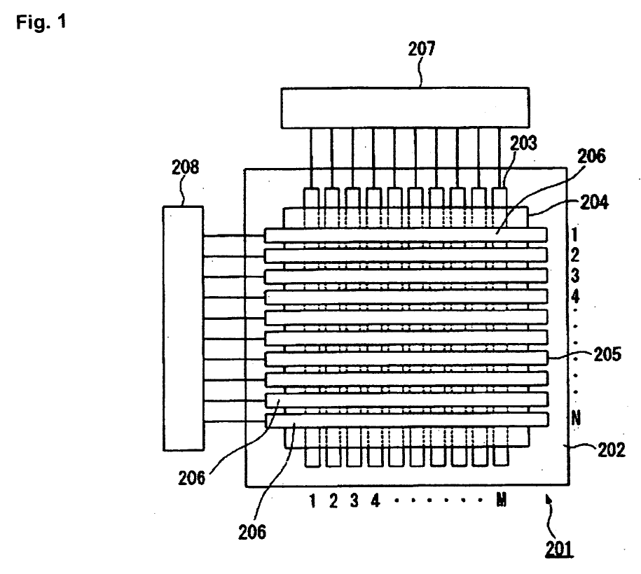

FIG. 1 is a schematic view illustrating a passive organic EL device according to a first exemplary embodiment of the invention and a control circuit thereof. A display panel 201 serves as a passive organic EL device. The display panel 201 can include a transparent substrate 202. On the surface of the transparent substrate 202, a plurality of stripe-like anodes 203 made of a transparent electrode material such as indium tin oxide (ITO) are juxtaposed to each other. Covering the plurality of anodes 203, an organic luminescent layer (luminescent layer) 204 is provided. On the upper surface of the organic luminescent layer 204, a plurality of stripe-like cathodes 205 made of a metal thin film are juxtaposed to each other. Accordingly, the organic luminescent layer 204 is sandwiched between the anodes 203 and the cathodes 205 in this arrangement. The anodes 203 and the cathodes 205 are perpendicular to each other. The organic luminescent layer 204 is provided at each intersection 206, serving as a pixel. In the example shown in FIG. 1, a plurality of pixels are arranged in an N×M matrix (N: 10; M: 10).

Each of the stripe-like anodes 203 is coupled to a data electrode driving part 207, while each of the stripe-like cathodes 205 is coupled to a scanning electrode driving part 208. The data electrode driving part 207 and the scanning electrode driving part 208 are controlled by a display controller. The display controller is controlled by a main controller that controls the whole operations of a panel by inputting video signals.

As the light emitting process of one frame period, the display panel 201 first makes the scanning electrode driving part 208 sequentially select each of the cathodes 205 in the first to Nth rows so that each row becomes conductive. To control the luminance of individual pixels in a selected row, the data electrode driving part 207 controls the conductivity of a column corresponding to a certain anode 203 (in the first to Mth columns) depending on the intensity of the video signals.

Since the display panel 201 serves as a passive organic EL device as mentioned above, it has a simpler element structure than that of an active organic EL device, and does not call for strict accuracy requirements. Therefore, it is possible to reduce manufacturing cost. In addition, manufacturing the display panel 201 according to the exemplary embodiment by the method or system for manufacturing an organic EL element according to one exemplary embodiment of the invention, which will be described in greater detail below, can further reduce manufacturing cost.

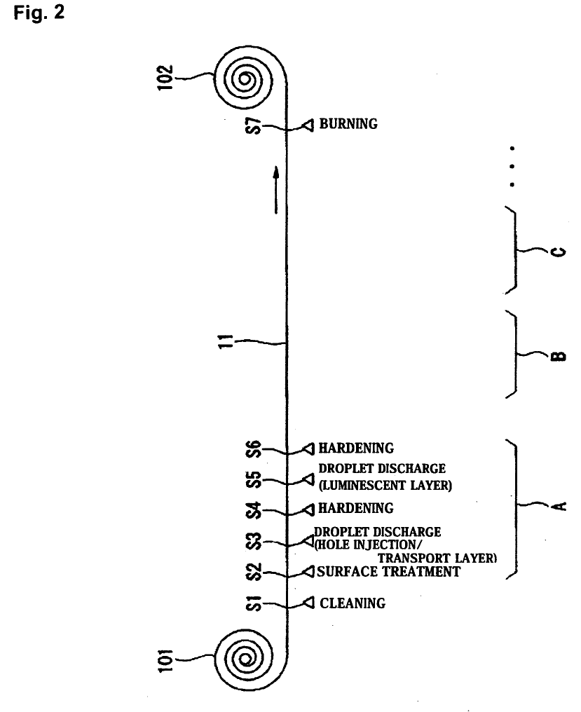

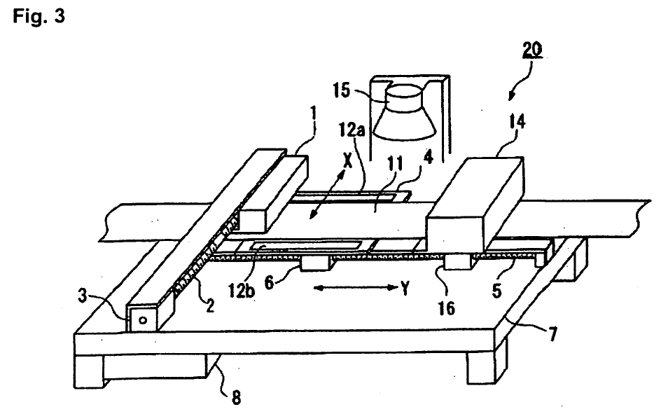

FIG. 2 is a schematic view illustrating the method for manufacturing an organic EL element and the system for manufacturing an organic EL element according to exemplary embodiments of the invention. In other words, FIG. 2 shows major steps for manufacturing the display panel 201 included in the passive organic EL device shown in FIG. 1. FIG. 3 is a perspective view showing an example of a droplet discharge device that is used in the method for manufacturing an organic EL element and is included in the system for manufacturing an organic EL element.

The system for manufacturing an organic EL element at least includes a first reel 101 around which a tape-like substrate 11 is wound, a second reel 102 that reels the tape-like substrate 11 pulled out from the first reel 101, and a droplet discharge device 20 that discharges a droplet onto the tape-like substrate 11. A patterning system here includes two units of (first and second) droplet discharge devices. The first droplet discharge device has a first discharge head (inkjet head group 1) for discharging a liquid substance containing the component of a hole injection/transport layer of the organic EL element as a droplet onto the tape-like substrate 11. The second droplet discharge device has a second discharge head (inkjet head group 1) for discharging a liquid substance containing the component of a luminescent layer of the organic EL element as a droplet. Here, the first and second droplet discharge devices have the same structure, namely, the droplet discharge device 20 shown in FIG. 3, except for the liquid substances they discharge.

The first droplet discharge device and the second droplet discharge device are placed near the tape-like substrate 11 as shown in FIG. 3. More specifically, the first droplet discharge device is placed closer to the first reel 101 than the second droplet discharge device. This way the inkjet head group 1 included in the first droplet discharge device is placed closer to the first reel 101 than the inkjet head group 1 included in the second droplet discharge device. Provided between the inkjet head group 1 included in the first droplet discharge device and the inkjet head group 1 included in the second droplet discharge device is a first drying device (not shown). The first drying device hardens the liquid substance containing the component of the hole injection/transport layer applied onto the tape-like substrate 11 by the inkjet head group 1 included in the first droplet discharge device. Provided between the inkjet head group 1 included in the second droplet discharge device and the second reel 102 is a second drying device (not shown).

Referring to FIG. 2, a first droplet discharge step (S3) can be performed by the first droplet discharge device. A first hardening step (S4) can be performed by the first drying device. A second droplet discharge step (S5) is performed by the second droplet discharge device. A second hardening step (S6) is performed by the second drying device.

The tape-like substrate 11 is, for example, a strip-shaped flexible substrate. The substrate is transparent. The tape-like substrate 11 is 105 mm wide and 200 m long, for example. The tape-like substrate 11 serves as a reel-to-reel substrate both of whose strip ends are reeled in the first reel 101 and the second reel 102. In other words, the tape-like substrate 11 pulled out from the first reel 101 is reeled in the second reel 102 and runs continuously in the longitudinal direction. The two units of the droplet discharge device 20 discharge a liquid substance as a droplet onto the tape-like substrate 11 running continuously, and thus provide patterns to be the hole injection/transport layer and the luminescent layer of the organic EL element.

This patterning system can also include a plurality of devices for performing a plurality of steps with one tape-like substrate 11 serving as a reel-to-reel substrate. Examples of the plurality of steps include steps for cleaning (S1), surface treatment (S2), first droplet discharge (S3), first hardening (S4), second droplet discharge (S5), second hardening (S6), and burning (S7). Through these steps, a multilayered structure composed of the hole injection/transport layer and the luminescent layer is provided to the tape-like substrate 11.

This patterning system also defines a large, desired substrate-forming area by dividing the tape-like substrate 11 into a predetermined length in the longitudinal direction. Accordingly, an organic EL device (display panel 201) is formed in each substrate-forming area through the following steps. The tape-like substrate 11 is moved continuously to each device used in each step, and thereby the hole injection/transport layer and the luminescent layer are continuously formed in each substrate-forming area of the tape-like substrate 11. As a result, the plurality of steps S1 through S7 are conducted on an assembly line, at once or in an overlapping time period with multiple devices.

The above-mentioned plurality of steps performed for the tape-like substrate 11 serving as a reel-to-reel substrate will now be described in greater detail.

A desired area on the tape-like substrate 11 pulled out from the first reel 101 is first cleaned in the cleaning step (S1).

The anodes 203 shown in FIG. 1 are preferably provided to the tape-like substrate 11 before this cleaning step (S1) or the surface treatment step (S2), which will be described later.

Specifically, the tape-like substrate 11 is irradiated with ultraviolet rays for the cleaning step (S1), for example. The tape-like substrate 11 may also be cleaned with water or other solvents, or with ultrasonic waves. Alternatively, the tape-like substrate 11 may also be cleaned by irradiating the tape-like substrate 11 with plasma at normal pressures.

Next, a desired area on the tape-like substrate 11 that has gone through the cleaning step (S1) is made lyophilic or lyophobic in the surface treatment step (S2).

A detailed example of the surface treatment step (S2) will now be described. To deposit a thin film made of the liquid substance containing the component of the hole injection/transport layer on the tape-like substrate 11 in the first droplet discharge step (S3), it is preferable to control surface wettability with the liquid substance in the desired area on the tape-like substrate 11. Here, the desired area means, for example, one area in which the hole injection/transport layer is provided and another area other than the one area on the tape-like substrate 11. Here, the area in which the hole injection/transport layer is provided on the tape-like substrate 11 is overlapped with the area in which the anodes 203 are provided. A method for surface treatment to produce a desired angle of contact will now be described.

According to the exemplary embodiment, the surface of the tape-like substrate 11 goes through two-step surface treatment. More specifically, it is made lyophobic and then made lyophilic to lessen the degree of lyophobicity. As a result, a certain angle of contact to the liquid substance containing the component of the hole injection/transport layer will be a desired value. This way one area in which the hole injection/transport layer is provided is made lyophilic, whereas the other area is made lyophobic, for example.

A method for making the surface of the tape-like substrate 11 lyophobic will now be explained. To provide lyophobic treatment, for example, a self-assembled film including an organic molecular film is provided on the surface of the substrate. The organic molecular film used for the surface treatment of the substrate includes a functional group that can combine with the substrate on one end, and a functional group that modifies the surface of the substrate (controlling surface energy) to be lyophobic, for example, on the other end. The organic molecular film can also include a linear or partially branched carbon chain that joins the functional groups together. Accordingly, a molecular film such as a monomolecular film is provided by combining with the substrate and self-assembling.

The self assembled film is a film provided by orienting a compound composed of a bonding functional group that can react with constituent atoms of an underlying layer (e.g., the substrate) and other linear chain molecules. The compound has extremely high orientation by means of interactions of the linear chain molecules. Since the self-assembled film is provided by orientating single molecules, the film can be deposited extremely thinly and evenly at the molecular level. In other words, since identical molecules are provided on the film surface, it is possible to provide an even and excellent lyophilic property etc. to the film surface.

By using, for example, fluoroalkylsilane as the above-mentioned compound having high orientation, each compound can be oriented so that the fluoroalkyl group is disposed on the film surface, and thereby forming a self-assembled film. As a result, an even lyophobic property is provided to the film surface.

Examples of the compound forming the self assembled film can include fluoroalkylsilane (FAS), such as heptadecafluoro-1,1,2,2-tetrahydrodecyl-triethoxysilane, heptadecafluoro-1,1,2,2-tetrahydrodecyl-trimethoxysilane, heptadecafluoro-1,1,2,2-tetrahydrodecyl-trichlorosilane, tridecafluoro-1,1,2,2-tetrahydrooctyl-triethoxysilane, tridecafluoro-1,1,2,2-tetrahydrooctyl-trimethoxysilane, tridecafluoro-1,1,2,2-tetrahydrooctyl-trichlorosilane, and trifluoropropyl trimethoxysilane. One of these compounds is preferably used alone, but it is also possible to use two or more of them in combination as long as they do not damage any advantages of the invention. Also according to the exemplary embodiment, it is preferable to use FAS as the compound forming the self-assembled film in order to provide good adhesiveness to the substrate and good lyophobicity.

The self-assembled film including an organic molecular film is provided on a substrate by placing any of the above-mentioned compounds and the substrate in the same air-tight container and leaving them for two to three days or so at room temperature. If the whole of the container is kept at 100 degrees Celsius, the film can be formed in about three hours. While a gas phase material is used in the above-described method, it is also possible to form the self-assembled film using a liquid phase material. For example, the self-assembled film is formed on a substrate by immersing the substrate in a solution containing any of the compounds and then washing and drying the substrate.

Prior to the forming of the self-assembled film, pretreatment, such as ultraviolet ray irradiation or cleaning with a solvent in the cleaning step (S1), is preferably conducted for the surface of the substrate.

Another example of lyophobic treatment is plasma irradiation at normal pressure. The type of gas used for this plasma treatment is selected, for example, depending on the surface material of the substrate. For example, fluorocarbon gases such as tetrafluoromethane, perfluorohexane, and perfluorodecane can be used as a treatment gas. In this case, a lyophobic, fluoride polymerized film can be provided on the surface of the substrate. The lyophobic treatment may also be provided by bonding a film having a desired lyophobic property, such as a polyimide film processed with tetrafluoroethylene, on the surface of the substrate. Here, a transparent polyimide film as it is can be used as the tape-like substrate 11.

A method for performing lyophilic treatment will now be described. The surface of the substrate that has gone through the lyophobic treatment has a higher lyophobic property than a desired one. Therefore, this lyophilic treatment lessens the degree of lyophobicity. To provide lyophilic treatment, the irradiation of ultraviolet rays of 170 to 400 nm can be performed, for example. Accordingly, the lyophobic film that has been provided can be partially and evenly damaged so as to lessen the degree of lyophobicity. In this case, the degree of lyophobicity to be lessened is adjusted by the time of ultraviolet ray irradiation, or by the intensity and wavelength of the ultraviolet rays and thermal treatment (heating) in combination.

Another example of lyophilic treatment is plasma treatment using oxygen as a reactant gas. Accordingly, the lyophobic film that has been provided can be partially and evenly modified so as to lessen the degree of lyophobicity.

Yet another example of lyophilic treatment is the exposure of the substrate to an ozone atmosphere. Accordingly, the lyophobic film that has been provided can be partially and evenly modified so as to lessen the degree of lyophobicity. In this case, the degree of lyophobicity to be lessened is adjusted by exposure output, distance and time, for example.

Next, to a desired area on the tape-like substrate 11 that has gone through the surface treatment step (S2), a liquid substance containing the component of a hole injection/transport layer is applied in the first droplet discharge step (S3). The first droplet discharge step (S3) is performed with the droplet discharge device 20 (first droplet discharge device) shown in FIG. 3. In other words, the first droplet discharge step (S3) is a step for providing a hole injection/transport layer by applying a liquid substance containing the component of the hole injection/transport layer to the desired area on the tape-like substrate 11 by droplet discharge.

Examples of the component of the hole injection/transport layer may include polythiophene derivatives, polypyrrole derivatives, and doping materials thereof. Specifically, 3,4-polyethylene dioxythiophene/polystyrene sulfonic acid (PEDOT/PSS) is used, for example.

For the application in the first droplet discharge step (S3), the first droplet discharge device 20 is filled with the component of the hole injection/transport layer. Then the inkjet head group 1 of the first droplet discharge device 20 is placed face to face with the surface of the anode (that has gone through the lyophilic treatment) provided on the tape-like substrate 11. The inkjet head group 1 is moved relatively to the tape-like substrate 11, and discharges a liquid substance containing the component of the hole injection/transport layer.

Here, the droplet discharged from the inkjet head group 1 spreads on the whole area for forming the hole injection/transport layer (the surface of the anode) that has gone through the lyophilic treatment. Meanwhile, the droplet is repelled and never attached on other areas than the area for forming the hole injection/transport layer, since they have gone through the lyophobic treatment. Accordingly, even if the droplet is out of a predetermined discharge position, the droplet rolls into the hole injection/transport layer.

Note that the first droplet discharge step (S3) and the following steps are preferably performed in an inactive gas atmosphere such as nitrogen and argon in order to prevent the oxidization of the hole injection/transport layer and the luminescent layer.

Also in the first droplet discharge step (S3), a droplet containing the component of the hole injection/transport layer is discharged from the inkjet head group 1 of the first droplet discharge device 20 onto a desired area on the tape-like substrate 11. Here, it is necessary to control the way droplets are discharged overlappingly in a row so as not to form a bulge of the droplets. It is possible to discharge a plurality of droplets in a way that they do not come in contact with each other for the first time, and the gap between the droplets are filled for the second and subsequent times.

Next, a desired area on the tape-like substrate 11 that has gone through the first droplet discharge step (S3) is subject to the first hardening step (S4) with a first drying device.

The first hardening step (S4) is a step for hardening the liquid substance containing the component of the hole injection/transport layer applied to the tape-like substrate 11 in the first droplet discharge step (S3). The first hardening step (S4) forms a thin film at least whose surface is hardened to be the hole injection/transport layer. The thickness of the thin film increases by repeating the steps S3 and S4 (and S2, possibly), and thereby easily providing the hole injection/transport layer of a desired shape to a desired thickness.

As a specific example of the first hardening step (S4), a liquid substance applied to the tape-like substrate 11 is dried for hardening, or more specifically, irradiated with ultraviolet rays for hardening. Alternatively, the tape-like substrate 11 may be heated with a hot plate or electric furnace, or is processed by lamp annealing as the first hardening step (S4). Examples of light sources for lamp annealing are not limited to but include: infrared lamp, xenon lamp, YAG laser, argon laser, carbon dioxide laser, and excimer laser of XeF, XeCl, XeBr, KrF, KrCl, ArF, ArCl, or the like. The light sources generally have the range from 10 W to 5000 W, but for the present embodiment it is sufficient to provide the range from 100 W to 1000 W.

Next, to a desired area on the tape-like substrate 11 that has gone through the first hardening step (S4), a liquid substance containing the component of the luminescent layer of the organic EL element is applied in the second droplet discharge step (S5) for forming the luminescent layer.

The second droplet discharge step (S5) can also performed with the droplet discharge device (second droplet discharge device) 20 shown in FIG. 3. Here, it is preferable to prepare the second droplet discharge device 20 used for the second droplet discharge step (S5) aside from the first droplet discharge device 20 for the first droplet discharge step (S3). Alternatively, two units of the inkjet head group 1 each for the first droplet discharge step (S3) and the second droplet discharge step (S5) may be included in one droplet discharge device 20 for both the first droplet discharge step (S3) and the second droplet discharge step (S5).

The second droplet discharge step (S5) is a step for applying a liquid substance containing the component of the luminescent layer with the droplet discharge device 20 in an upper layer of the thin film to be the hole injection/transport layer on the tape-like substrate 11 that has been provided through the first droplet discharge step (S3) and the first drying step (S4). In other words, the liquid substance containing the component of the luminescent layer film is applied to the whole of a predetermined area (area in which the luminescent layer is to be formed) on the tape-like substrate 11 with the droplet discharge device 20. Prior to the second droplet discharge step (S5), surface treatment corresponding to the above-described surface treatment step (S2) is preferably performed. For example, the whole of the area in which the luminescent layer is to be formed on the tape-like substrate 11 is preferably made lyophilic.

Next, a desired area on the tape-like substrate 11 that has gone through the second droplet discharge step (S5) is subject to the second hardening step (S6).

The second hardening step (S6) is a step for hardening the liquid substance containing the component of the luminescent layer applied to the tape-like substrate 11 in the second droplet discharge step (S5). The second hardening step (S6) forms a thin film at least whose surface is hardened to be the luminescent layer. As a specific example of the second hardening step (S6), a liquid substance applied to the tape-like substrate 11 is dried for hardening, or more specifically, irradiated with ultraviolet rays for hardening. The thickness of the thin film increases by repeating the steps S5 and S6 (and surface treatment, possibly), and thereby easily forming the thin film to be the luminescent layer of a desired shape to a desired thickness. Note that specific examples of the second hardening step (S6) are the same as those of the above-described first drying step (S4).

The steps S2 to S6 make up a first area processing step A for providing a multilayered structure composed of a thin film to be the hole injection/transport layer and a thin film to be the luminescent layer in a first area included in a plurality of areas of the tape-like substrate 11 divided in the longitudinal direction. Here, since one organic EL device is provided in each of the divided areas of the tape-like substrate 11, one organic EL device is provided in the first area.

After the first area processing step A, the tape-like substrate 11 is moved in its longitudinal direction, and then the steps S2 to S6 are performed for a second area that is next to the first area out of the plurality of areas. Accordingly, a multilayered structure composed of a thin film to be the hole injection/transport layer and a thin film to be the luminescent layer is provided in the second area of the tape-like substrate 11. The processing for the second area is a second area processing step B.

After the second area processing step B, a third area processing step C is performed in a third area that is next to the second area of the tape-like substrate 11 in the same way as the second area processing step B. Subsequently, the same processing as the second area processing step B is repeated for the tape-like substrate 11 so as to provide a multilayered structure composed of a thin film to be the hole injection/transport layer and a thin film to be the luminescent layer in each of the plurality of areas on the tape-like substrate 11.

The first area processing step A, the second area processing step B, the third area processing step C, and so on, are followed by the burning step (S7) for burning the multilayered structure of the thin films on the tape-like substrate 11.

The burning step (S7) is a step for burning the thin film to be the hole injection/transport layer that has been applied in the first droplet discharge step (S3) and then hardened, and the thin film to be the luminescent layer that has been applied in the second droplet discharge step (S5) and then hardened at the same time. Through the burning step (S7), the multilayered structure composed of the hole injection/transport and luminescent layers is completed on the tape-like substrate 11.

The burning step (S7) is usually carried out in the atmosphere, and can also be carried out in an inert gas atmosphere of nitrogen, argon, helium, or the like if necessary. The processing temperature in the burning step (S7) is determined depending on, for example, the boiling point (vapor pressure) of a dispersion medium contained in the liquid substance applied in the first droplet discharge step (S3) or second droplet discharge step (S5), the type and pressure of the atmospheric gas, thermal behaviors such as fine-particle dispersibility and oxidizability, the use and volume of coating materials, and the allowable temperature limit of the base material. For example, a desired area on the tape-like substrate 11 is burned at 150 degrees Celsius in the burning step (S7).

A hot plate or electric furnace is usually used for this burning. Alternatively, lamp annealing can also be employed. It should be understood that examples of light sources for lamp annealing are not limited to, but can also include: infrared lamp, xenon lamp, YAG laser, argon laser, carbon dioxide laser, and excimer laser of XeF, XeCl, XeBr, KrF, KrCl, ArF, ArCl, or the like. The light sources generally have the range from 10 W to 5000 W, but for the exemplary embodiment it is sufficient to provide the range from 100 W to 1000 W.

The desired area on the tape-like substrate 11 that has gone through the burning step (S7) is temporality reeled in the second reel 102. Subsequently, a cathode etc. is provided in an upper layer of the luminescent layer that has been provided on the tape-like substrate 11. The forming of the cathode etc. is performed by droplet discharge in the same way as the above-described first droplet discharge step (S3). This way, an organic EL device is provided in each of the plurality of areas on the tape-like substrate 11. Separating the tape-like substrate 11 into each area completes a large number of organic EL devices (each corresponding to the display panel 201 shown in FIG. 1).

According to the exemplary embodiment, the hole injection/transport layer and the luminescent layer are provided by droplet discharge on the tape-like substrate 11 serving as a reel-to-reel substrate. Accordingly, the hole injection/transport layer and the luminescent layer are provided by droplet discharge in each area of the tape-like substrate 11 while moving the tape-like substrate 11 in its longitudinal direction in the present embodiment, and thereby mass producing passive organic EL devices economically and promptly.

Also in the exemplary embodiment, it is possible to perform the first droplet discharge step (S3) (and/or the first hardening step S4) for forming the hole injection/transport layer and the second droplet discharge step (S5) (and/or the second hardening step S6) for forming the luminescent layer to one tape-like substrate 11 in an overlapping time period. For example, while the first droplet discharge step (S3) is performed with respect to the second area of the tape-like substrate 11 with the first droplet discharge device 20, the second droplet discharge step (S5) may be performed with respect to the first area (that has been subject to the step for forming the hole injection/transport layer) of the tape-like substrate 11 with the second droplet discharge device. Also, each of the steps for cleaning (S1), surface treatment (S2), first droplet discharge (S3), first hardening (S4), second droplet discharge (S5), second hardening (S6), and burning (S7) can be performed in an overlapping time period. According to the exemplary embodiment, the steps for cleaning (S1), surface treatment (S2), first droplet discharge (S3), first hardening (S4), second droplet discharge (S5), second hardening (S6), and burning (S7) can be performed for the tape-like substrate 11 like in a conveyor system, and thereby manufacturing hole injection/transport and luminescent layers of a large number of organic EL devices efficiently and promptly. Also according to the exemplary embodiment, it is possible to simplify the mechanism for moving and aligning the tape-like substrate 11 to each device for each step, and thereby reducing the space required for manufacturing devices. As a result, it is possible to significantly reduce the cost of mass production of organic EL devices.

In the patterning system and method according to the exemplary embodiment, time required for each of the plurality of steps is preferably almost the same. This makes it possible to conduct one step in sync with another, and thereby prompting manufacturing and further enhancing the efficiency in the use of each device in each step. Here, it is possible to adjust the number and performance of the devices used in each step (e.g., the droplet discharge device 20) in order to equalize time required for each step. For example, if much time is required for the second droplet discharge step (S5) than for the first droplet discharge step (S3), two droplet discharge devices (each corresponding to the droplet discharge device 20) can be used for the second droplet discharge step (S5), while one droplet discharge device 20 is used for the first droplet discharge step (S3).

The droplet discharge device 20 will now be described in greater detail referring to the accompanying drawing. As shown in FIG. 3, the droplet discharge device 20 can include the inkjet head group (discharge head) 1, an X-direction guide axis (guide) 2 for driving the inkjet head group 1 in the X direction, and an X-direction driving motor 3 for rotating the X-direction guide axis 2. The droplet discharge device 20 can also include a stage 4 on which the tape-like substrate 11 is placed, a Y-direction guide axis 5 for driving the stage 4 in the Y direction, and a Y-direction driving motor 6 for rotating the Y-direction guide axis 5. The droplet discharge device 20 also includes a base 7 on which the X-direction guide axis 2 and the Y-direction guide axis 5 are fixed to predetermined positions, and a controller 8 placed below the base 7. The droplet discharge device 20 further includes a cleaning mechanism part 14 and a heater 15.

Here, the X-direction guide axis 2, the X-direction driving motor 3, the Y-direction guide axis 5, the Y-direction driving motor 6, and the stage 4 make up a head moving mechanism for moving the inkjet head group 1 relatively to the tape-like substrate 11 that is aligned to the stage 4. The X-direction guide axis 2 is a guide that moves the inkjet head group 1 in the direction (X direction) almost perpendicular to the longitudinal direction of the tape-like substrate 11 (Y direction) during a droplet discharge operation from the inkjet head group 1.

The inkjet head group 1 can include a plurality of inkjet heads that eject a dispersion liquid (liquid substance) containing conductive fine particles, for example, from its nozzle (discharge outlet) onto the tape-like substrate 11 at a predetermined interval. Each of the plurality of inkjet heads individually ejects the dispersion liquid depending on a discharge voltage that is output from the controller 8. The inkjet head group 1 is fixed to the X-direction guide axis 2, which is coupled to the X-direction driving motor 3. The X-direction driving motor 3 is a stepping motor, for example, and rotates the X-direction guide axis 2 when a driving pulse signal in the X-axis direction is supplied by the controller 8. Upon the rotation of the X-direction guide axis 2, the inkjet head group 1 moves in the X-axis direction with respect to the base 7.

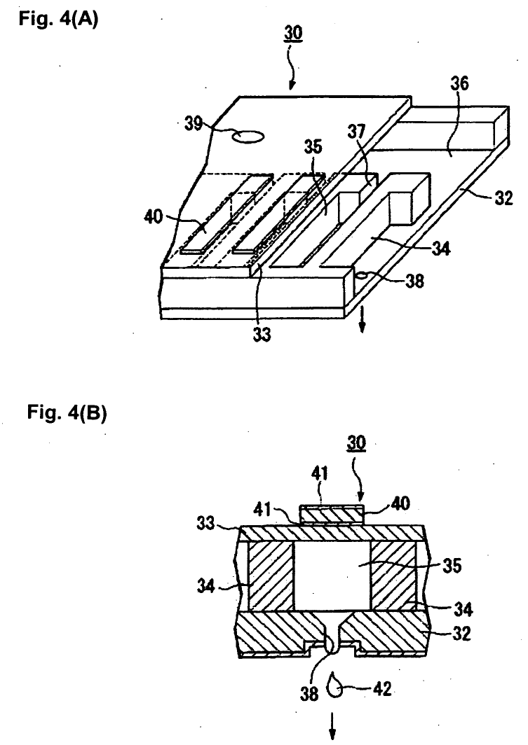

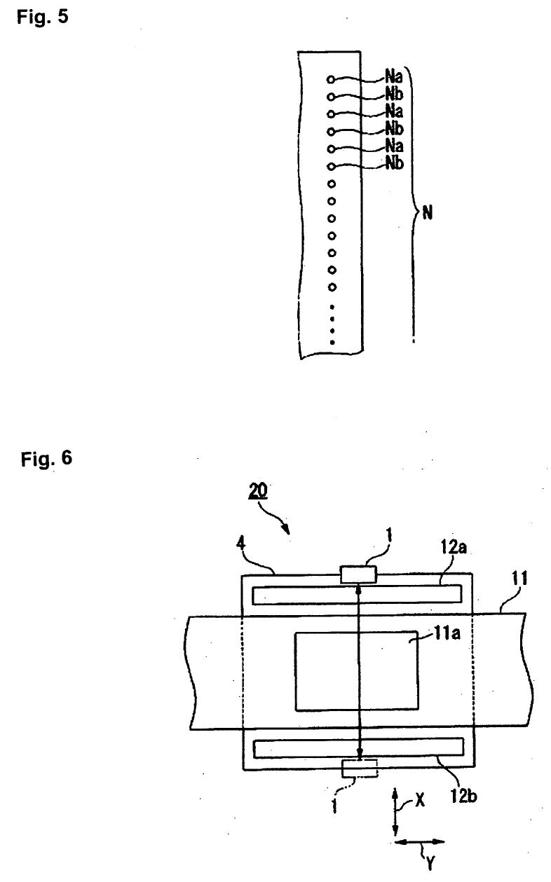

The plurality of inkjet heads making up the ink-jet head group 1 will now be described in greater detail. FIG. 4A is a perspective view and FIG. 4B is a sectional view showing major elements of an inkjet head 30. FIG. 5 is a bottom view of the inkjet head 30.

As shown in FIG. 4A, the inkjet head 30 can include, for example, a stainless nozzle plate 32 and diaphragm 33 that are joined with a partition member (reservoir plate) 34 therebetween. Provided between the nozzle plate 32 and the diaphragm 33 are a plurality of cavities 35 defined by the partition member 34, and a reservoir 36. Each of the cavities 35 and the reservoir 36 are filled with a liquid substance. Each of the cavities 35 is communicated with the reservoir 36 via a feed opening 37. The nozzle plate 32 is provided with a plurality of nozzle orifices 38 arranged in a matrix for ejecting the liquid substance from the cavity 35. Meanwhile, the diaphragm 33 is provided with a hole 39 for supplying the liquid substance to the reservoir 36.

A piezoelectric element 40 can be joined onto the side of the diaphragm 33 opposite to the side facing the cavity 35, as shown in FIG. 4B. The piezoelectric element 40 is disposed between a couple of electrodes 41, and is bent in a way that it protrudes outward with electricity. The diaphragm 33 to which the piezoelectric element 40 is thus joined is bent outward integrally with the piezoelectric element 40. This increases the volume of the cavity 35. Accordingly, the liquid substance of the increased volume inside the cavity 35 is flown from the reservoir 36 via the feed opening 37. When the piezoelectric element 40 is deenergized from this state of things, the piezoelectric element 40 and the diaphragm 33 revert to their original shapes. Thus, the cavity 35 also reverts to its original volume and the pressure of the liquid substance inside the cavity 35 increases. As a result, a liquid droplet 42 is ejected from the nozzle orifices 9 onto the substrate.

The inkjet head 30 of the above-described structure has a substantially rectangular bottom in which nozzles N (nozzle orifices 38) are arranged lengthwise at a fixed interval in a rectangle as shown in FIG. 5. The nozzles arranged lengthwise in this example are main nozzles (first nozzles) Na and sub nozzles (second nozzles) Nb that are arranged alternately.

Each of the nozzles N (nozzles Na, Nb) can be provided with the piezoelectric element 40 individually, and therefore its discharge is operated individually. In other words, by controlling the waveform of discharge as an electrical signal to be sent to the piezoelectric element 40, the amount of droplets discharged from each nozzle N can be adjusted and changed. Here, the controller 8 controls the waveform of discharge. The controller 8 functions as a discharge amount controller that changes the amount of droplets discharged from each nozzle N.

Examples of methods employed for the inkjet head 30 are not limited to piezoelectric jetting using the piezoelectric element 40, but also include a thermal method in which the amount of droplet discharge are changed by changing application time.

Referring back to FIG. 3, the stage 4 carries the tape-like substrate 11 to which a dispersion liquid is applied by the droplet discharge device 20. The stage 4 includes a mechanism (alignment mechanism) for fixing the tape-like substrate 11 at a reference position. The stage 4 is fixed to the Y-direction guide axis 5, which is coupled to Y-direction driving motors 6, 16. The Y-direction driving motors 6, 16 are stepping motors, for example, and rotate the Y-direction guide axis 5 when a driving pulse signal in the Y-axis direction is supplied by the controller 8. Upon the rotation of the Y-direction guide axis 5, the stage 4 moves in the Y-axis direction with respect to the base 7.

The droplet discharge device 20 includes the cleaning mechanism part 14 that cleans the inkjet head group 1. The cleaning mechanism part 14 is moved along the Y-direction guide axis 5 by the Y-direction driving motor 16. The controller 8 also controls the movement of the cleaning mechanism part 14. Flushing areas 12a, 12b of the droplet discharge device 20 will now be described.

FIG. 6 is a partial plan view of the droplet discharge device 20 around the inkjet head group 1. The stage 4 included in the droplet discharge device 20 is provided with two flushing areas 12a, 12b. The flushing areas 12a, 12b are areas disposed on each end of the tape-like substrate 11 in the transverse direction (X direction). The inkjet head group 1 can be moved to the flushing areas 12a, 12b by the X-direction guide axis 2. In other words, the flushing areas 12a, 12b are disposed on each side of a desired area 11a corresponding to one circuit substrate in the tape-like substrate 11. The flushing areas 12a, 12b are also areas in which a dispersion liquid (liquid substance) is dropped by the inkjet head group 1. By arranging the flushing areas 12a, 12b this way, the inkjet head group 1 can be moved to either the flushing area 12a or 12b promptly along the X-direction guide axis 2. For example, in order for the inkjet head group 1 to flush around the flushing area 12b, this arrangement allows swift flushing by moving the inkjet head group 1 to the flushing area 12b that is nearer to the target area without moving the inkjet head group 1 to the flushing area 12a that is farther to the target area.

The heater 15 is a part for providing the tape-like substrate 11 with thermal treatment (drying or burning) by lamp annealing. In other words, the heater 15 not only evaporates and dries a liquid substance discharged on the tape-like substrate 11, but also provides thermal treatment for turning the substance into a conductive film. Here, the controller 8 also controls turning on and off of the heater 15. This way, the heater 15 can provide any or all of the above-described first hardening step (S4), second hardening step (S6), and burning step (S7) shown in FIG. 2.

As for the droplet discharge device 20 according to the exemplary embodiment, the controller 8 provides the X-direction driving motor 3 and/or the Y-direction driving motor 6 with a predetermined driving pulse signal for moving the inkjet head group 1 and/or the stage 4 so as to discharge a dispersion liquid to a predetermined wiring-forming area. Thus, the inkjet head group 1 and the tape-like substrate 11 (stage 4) are relatively moved. While relatively moving them, the controller 8 provides a predetermined inkjet head 30 included in the inkjet head group 1 with a discharge voltage, and thereby making the inkjet head 30 discharge the dispersion liquid.

With the droplet discharge device 20 according to the exemplary embodiment, the amount of droplets discharged by each inkjet head 30 included in the inkjet head group 1 can be adjusted by the discharge voltage supplied by the controller 8. Also, the pitch of droplets discharged onto the tape-like substrate 11 is determined by the rate of relative movement between the inkjet head group 1 and the tape-like substrate 11 (stage 4) and the frequency of the discharge from the inkjet head group 1, that is, the frequency of discharge voltage supply.

The droplet discharge device 20 according to the exemplary embodiment makes a droplet land on any position in a desired area on the tape-like substrate 11 to form a pattern by moving the inkjet head group 1 along the X-direction guide axis 2 or the Y-direction guide axis 5. Also, after forming the pattern in one desired area, it is possible to readily form a pattern in another desired area by moving the tape-like substrate 11 in its longitudinal direction (Y direction). Here, the desired area may correspond to one circuit substrate. Accordingly, the exemplary embodiment makes it possible to easily and promptly form a pattern in each desired area (each organic-EL-device-forming area) on the tape-like substrate 11, and efficiently mass produce hole injection/transport and luminescent layers included in the organic EL device.

Note that the patterning system according to the exemplary embodiment preferably has a structure in which the second reel 102 reels the tape-like substrate 11 so that the side of the tape-like substrate 11 on which a liquid substance is applied by the droplet discharge device 20 faces inward. Moreover, the inner side of the tape-like substrate 11 reeled in the first reel 101 is the surface on which the liquid substance is applied by the droplet discharge device 20.

Accordingly, the tape-like substrate 11 is reeled in the second reel 102 in the way that the side of the tape-like substrate 11 on which the pattern has been formed faces inward, and thereby maintaining the pattern in a favorable condition. Also, since the tape-like substrate 11 is bent in the same direction at both the first reel 101 and the second reel 102, it is possible to reduce an external mechanical force imposed on the tape-like substrate 11, and thereby reducing the deformation etc. of the tape-like substrate 11.

In the patterning system according to the exemplary embodiment, the droplet discharge device 20 may include one or more inkjet head groups 1 that can discharge a droplet on the front and back sides of the tape-like substrate 11 almost at once. As the droplet discharge device 20, a structure including the inkjet head groups 1 arranged on the front and back sides of the tape-like substrate 11 is applicable that maintains the front side of the tape-like substrate 11 in a vertical state. Accordingly, a thin-film pattern can be formed the front and back sides of the tape-like substrate 11 at once, and thereby further reducing time and cost required for manufacturing the organic EL device. For example, hole injection/transport layer and luminescent layers are provided on the front side of the tape-like substrate 11, while a circuit serving as the data electrode driving part 207 and the scanning electrode driving part 208 shown in FIG. 1 are provided on the back side of the tape-like substrate 11.

Furthermore, the patterning system according to the exemplary embodiment may include an inversion mechanism (not shown) that inverts of the tape-like substrate 11 to its front and back sides. The droplet discharge device 20 preferably includes a first inkjet head group that discharges a droplet on the upper side of the tape-like substrate 11 that has yet to be inverted by the inversion mechanism and a second inkjet head group that discharges a droplet on the upper side of the tape-like substrate 11 that has been inverted by the inversion mechanism.

This structure, in which the inversion mechanism inverts the tape-like substrate 11, enables the first inkjet head group to apply the droplet on one side of the tape-like substrate 11 and the second inkjet head group to apply the droplet on the other side of the tape-like substrate 11. Accordingly, a liquid substance can be applied on the both sides of the tape-like substrate 11 by droplet discharge.

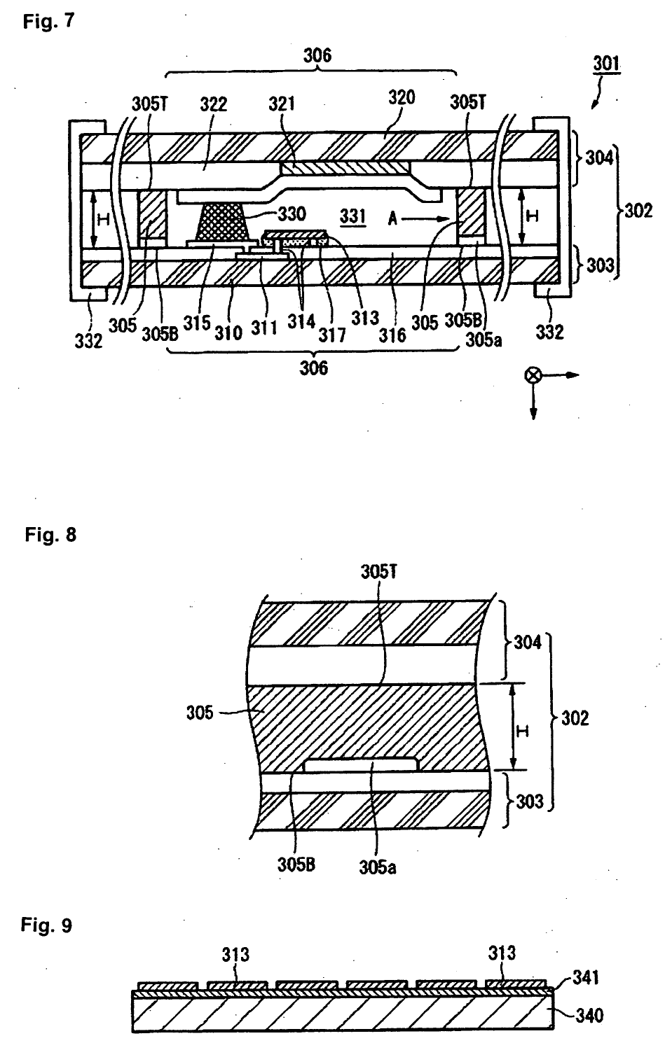

FIG. 7 is a sectional view schematically showing a main structure of an active organic EL device according to a second exemplary embodiment of the invention. FIG. 8 is a side view seen from the direction A in FIG. 7. Note that scales of members in the drawings referred to herein are adequately changed so that they are visible.

The active organic EL device includes an active device, such as TFT, and a charge storage capacitor for each pixel. Here, the TFT cannot be directly provided on the film serving as the tape-like substrate 11. Therefore, the TFT is provided to a base substrate other than the tape-like substrate 11, and the base substrate is joined to the tape-like substrate 11 so as to transfer the TFT to the tape-like substrate 11. Subsequently, hole injection/transport and luminescent layers are provided in an upper layer of the TFT by the process shown in FIG. 2, which completes the active organic EL device.

Here, it is possible to manufacture the active organic EL device by applying the above-described TFT transferring method and using the tape-like substrate 11 as follows. First, a TFT is provided to a base substrate other than the tape-like substrate 11, and then a wiring substrate other than the tape-like substrate 11 and the base substrate is also provided. Subsequently, the base substrate is joined to the wiring substrate so as to transfer the TFT on the base substrate to the wiring substrate. Also, an organic EL device including hole injection/transport and luminescent layers are provided on the tape-like substrate 11 by the method according to the first embodiment. Then, the wiring substrate on which the TFT has been transferred is joined to the tape-like substrate 11 on which the organic EL device is provided, which completes the active organic EL device.

This way fewer processes are required after providing or transferring a drive element, such as TFT, for a drive circuit substrate (wiring substrate), and thereby substantially reducing the possibility of damaging the drive element in the manufacturing process. Also, since the electro-optical substrate (the tape-like substrate 11) and the drive circuit substrate are manufactured in separate steps, the yield can be increased. It is also possible to provide the electro-optical substrate and the drive circuit substrate that are manufactured by different plants or manufacturers to join the two substrates together, which is highly advantageous in reducing manufacturing costs. Also, it is possible to manufacture a wide-screen electro-optical device with a comparatively low investment in plant and equipment. Now, the organic EL device according to the exemplary embodiment in which the TFT transferring method is applied and a manufacturing method thereof will be described in greater detail.

As shown in FIG. 7, an organic EL device 301 according to the exemplary embodiment at least includes a joined substrate 302. The joined substrate 302 includes a wiring substrate (first substrate, drive circuit substrate) 303 and an organic EL substrate (second substrate, electro-optical substrate) 304 that are joined together with conductive parts 305, 330 that will be described later therebetween. Here, the organic EL substrate 304 is provided with, for example, an organic EL element 321 including hole injection/transport and luminescent layers provided on the tape-like substrate 11 by the process shown in FIG. 2.

The wiring substrate 303 includes a substrate 310, a wiring pattern 311 of a predetermined shape provided on the substrate 310, a TFT (drive element) 313 for driving the organic EL element (luminescent element) 321, a TFT coupling part 314 for joining the TFT 313 with the wiring pattern 311, an organic EL coupling part (terminal part) 315 for joining the organic EL element 321 with the wiring pattern 311, and an interlayer insulating film 316. The TFT coupling part 314 is formed corresponding to the terminal pattern of the TFT, and is composed of a bump formed by electroless plating and a conductive paste applied on the bump by coating process. A conductive paste 317 includes anisotropic conductive particles (ACP).

The organic EL substrate 304 can be formed by the process shown in FIG. 2. The organic EL substrate 304 includes a transparent substrate 320 (the tape-like substrate 11) through which light is transmitted, the organic EL element 321, an insulating film 322, and a cathode (luminescent element) 325.

The organic EL element 321 includes an anode made of a transparent metal material such as indium tin oxide (ITO), a hole injection/transport layer, and an organic EL element (luminescent layer). Light is emitted when a hole produced at the anode and an electron produced at the cathode join together at the organic EL element. Here, known methods can be used to make the detailed structure of this organic EL element. An electron injection/transport layer may also be provided between the organic EL element 321 and the cathode 325.

Provided between the wiring substrate 303 and the organic EL substrate 304 are a rib 305, the conductive part 330 for making a conductive coupling between the organic EL coupling part 315 and the cathode 325, and a sealing part 332 for sealing the periphery of the substrates 303, 304. A space between the substrates 303, 304 is filled with an inert gas 331.

The rib 305 is provided to surround an area 306 in which one TFT 313 and one organic EL element 321 are provided. The rib 305 is arranged in a matrix on the X-Y plane in the organic EL device 301 when viewed from above. The height H of the rib 305 in the organic EL device 301 is fixed. The wiring substrate 303 and the organic EL substrate 304 are separated from each other by the space of this height. The surfaces of a bottom part 305B and an upper part 305T of the rib 305 are highly adhesive, and thereby the wiring substrate 303 and the organic EL substrate 304 are joined with the rib 305 therebetween.

As shown in FIG. 8, the rib 305 can be provided with a through-hole (through-hole part) 305a that makes the area 306 communicate with another neighboring area. The height H of the rib 305 is determined so that the conductive part 330 can be preferably deformed. In other words, the height H is set lower than the height of the conductive part 330 before joining.

While the rib 305 is provided so as to form one TFT 313 and one organic EL element 321 for each area 306 in the present embodiment, the rib 305 may also be provided in a way that a plurality of TFTs (each corresponding to the TFT 313) and organic EL elements (each corresponding to the organic EL element 321) are formed in each area 306. For example, plural types of organic EL elements 321 for emitting light of red (R), green (G) and blue (B) may be arranged in the area 306. Furthermore, depending on various design requirements for the organic EL device 301, it is preferable that the rib 305 is provided for each area 306 having one or more elements (the organic EL element 321 or the TFT 313). For example, joining strength is higher when providing the rib 305 for each element than providing the rib 305 for a plurality of elements.

For example, when joining strength between the wiring substrate 303 and the organic EL substrate 304 is substantially high, it is unnecessary to provide the rib 305 for each element. Providing the rib 305 for a plurality of elements can join the wiring substrate 303 and the organic EL substrate 304 while maintaining certain joining strength.

Therefore, it is possible to provide the rib 305 by determining the number of elements in an area taking design requirements for the organic EL device 301 such as manufacturing cost and difficulties into account. Furthermore, the rib 305 is not necessarily arranged in a matrix, and may be arranged in the direction in which the TFT 313 or the organic EL element 321 is arranged (in the X- or Y-direction in FIG. 7).

The conductive part 330 can be silver paste, and changes shape when pressed to join the wiring substrate 303 and the organic EL substrate 304 together. The material is not necessarily paste as long as it is a conductive and flexible silver material. Also, any preferable conductive materials can be used here.

The inert gas 331 can be selected among known types of gases. Nitrogen (N₂) gas is used for the exemplary embodiment. Alternatively, rare gases such as Ar are preferably used. Mixed gases can be also used as long as they are inert. The inert gas 331 is filled around a step of joining the wiring substrate 303 and the organic EL substrate 304 together as described later. Since the rib 305 has the through-hole 305a, the inert gas 331 in an area next to the area 306 flows into or out of the area 306 through the through-hole 305a. Here, a material filling the space between the wiring substrate 303 and the organic EL substrate 304 is not necessarily an air, and an inert liquid can be used alternatively.

The sealing part 332 provides can sealing and is disposed around the periphery of the wiring substrate 303 and the organic EL substrate 304. Note that other methods than can sealing (e.g. sealing resin) can be used here. Any methods can be preferably used as long as they prevent a substance that deteriorates the organic EL element 321 from being mixed. Also, an absorbent material for absorbing moisture that deteriorates the organic EL element 321 may be provided in between the wiring substrate 303 and the organic EL substrate 304.

A method for manufacturing the organic EL device 301 shown in FIG. 7 will now be described with reference to the accompanying drawings.

Referring to FIG. 9, a step for providing TFT on the base substrate 340 prior to joining and transferring the TFT 313 to the wiring substrate 303 will be described.

Since the TFT 313 can be manufactured by a known technique including high-temperature processing, the description thereof will be omitted. The base substrate 340 and a separating layer 341 will be described in detail.

The base substrate 340 is a member that is used only for manufacturing, joining and transferring the TFT, and is not an element of the organic EL device 301. The base substrate 340 is preferably a translucent heat-resisting substrate made of quartz glass or the like that withstands temperatures up to about 1000 degrees Celsius. Aside from quartz glass, heat resistant glass, such as soda glass, Corning 7059, Nippon Electric Glass OA-2, etc., can be used here.

Although the thickness of the base substrate is not strictly limited, a thickness of around 0.1 mm to 0.5 mm is preferable, and from 0.5 mm to 1.5 mm is more preferable. If the base substrate is too thin, its strength reduces. Meanwhile, if the base substrate is too thick, it causes attenuation of irradiation light with a low transmittance rate of a base. With a high transmittance rate of irradiation light of the base, the base substrate can be thicker than the above-mentioned upper limit.

The separating layer 341 is made of a material inside or on the boundary of which separation (also referred to as inter-layer separation or boundary separation) takes place when irradiated with laser light or the like. More specifically, with the irradiation of light of a certain intensity, the interatomic or intermolecular bonding force of atoms or molecules composing the substance is reduced or obliterated, and thereby the resulting ablation causes such separation. Here, components contained in the separating layer 341 are released as a gas in some cases, and thereby the separation takes place. In other cases, the separating layer 341 absorbs light, turning its components to gas, and thereby the gas evaporates, which causes the separation.

The separating layer 341 is composed of amorphous silicon (a-Si), for example. The amorphous silicon may contain hydrogen (H). Hydrogen is preferably contained since hydrogen released by light irradiation develops inner pressure in the separating layer 341, which promotes the separation. In this case, the content of hydrogen is preferably about 2 at % or more, and more preferably, from 2 to 20 at %. The content of hydrogen is adjusted by appropriately setting deposition conditions when employing chemical vapor deposition (CVD), such as gas composition, gas pressure, gas atmosphere, gas flow, gas temperature, substrate temperature, and applied power. Other examples of materials of the separating layer include silicon oxide, silicate compounds, silicon nitride, aluminum nitride, titanium nitride and other nitride ceramics, organic polymer materials whose interatomic bonds are broken when irradiated with light, metal materials such as Al, Li, Ti, Mn, In, Sn, Y, La, Ce, Nd, Pr, Gd, and Sm, and alloys containing at least one of the metal materials.

The thickness of the separating layer 341 is preferably about 1 nm to 20 μm, more preferably about 10 nm to 2 μm, and further preferably about 20 nm to 1 μm. If the separating layer 341 is too thin, it cannot be formed evenly, which results in uneven separation on one hand. On the other, if the separating layer 341 is too thick, the separation requires intensive (or a large amount of) irradiation light. Furthermore, it takes time to remove a residue of the separating layer 341 after the separation.

The separating layer 341 can be formed by any method that are capable of forming the separating layer 341 to an even thickness. An appropriate method is selected depending on various conditions, such as the composition or thickness of the separating layer 341. These methods can include CVD (including MOCCVD, low-pressure CVD, ECR-CVD), vapor deposition, molecular beam deposition (MB), sputtering, ion doping, PVD and other vapor deposition methods; electroplating, dipping, electroless plating and other plating methods, Langmuir Blodgett (LB), spin coating, spray coating, roll coating and other coating methods, printing methods, transferring methods, ink jetting, and powder jetting. Moreover, two or more of the above-mentioned methods can be used in combination.

If the separating layer 341 is composed of amorphous silicon (a-Si) in particular, CVD, particularly low-pressure CVD and plasma CVD can be preferably used for deposition. If the separating layer 341 is deposited with ceramics by a sol-gel method, or with an organic polymer material, a coating method, in particular spin coating can be preferably used for deposition.

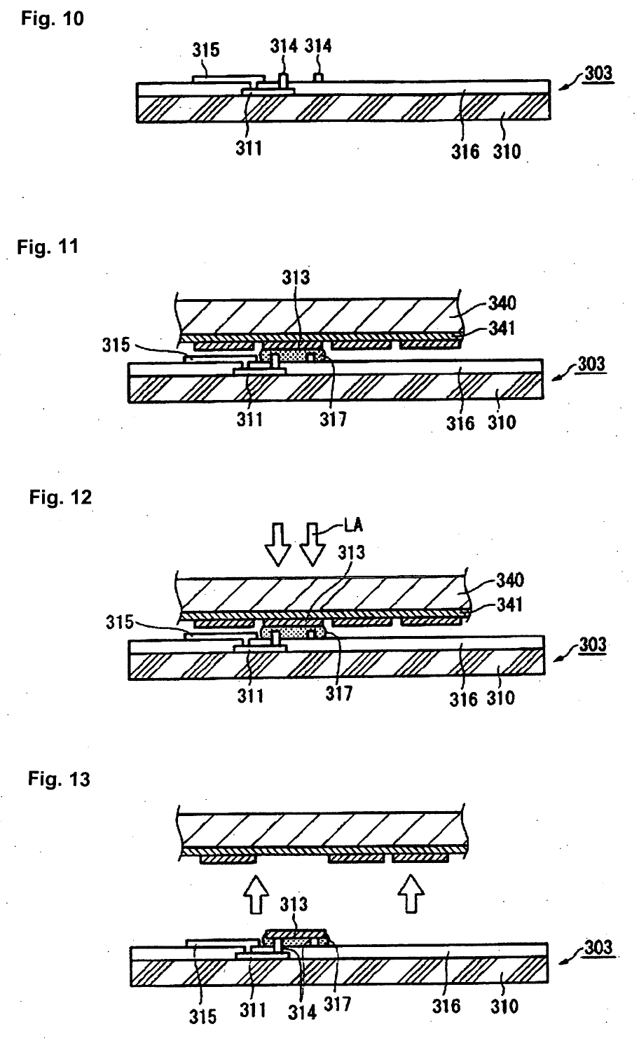

In parallel with the step for manufacturing the base substrate 340 shown in FIG. 9, a step for manufacturing the wiring substrate 303 shown in FIG. 10 is performed.

Referring to FIG. 10, the wiring pattern 311, the interlayer insulating film 316, the TFT coupling part 314, and the organic EL coupling part 315 are provided on the substrate 310 sequentially. As a method for forming a wiring pattern, a known technique, such as photolithography can be adopted. Also, a dispersion liquid in which fine metallic particles are dispersed in a solvent can be used for forming a wiring pattern on the substrate 310. To provide the wiring pattern 311, materials with low resistance values such as Al and Al alloys (e.g. Al—Cu alloy) can preferably be used.

On the surface of the substrate 310, a silicon oxide film (SiO₂) or the like may be formed as an underlying insulating film. While one-layer wiring pattern is shown in FIG. 10, two- or three-layer pattern can also be provided. The wiring materials are not limited to Al and Al alloys, and may have a sandwich structure in which a metal material with a low resistance value such as Al is multilayered with Ti or Ti compounds. Accordingly, it is possible to increase barrier and hillock resistance to the Al wiring.

The interlayer insulating film 316 is then provided on the wiring pattern 311. The interlayer insulating film 316 is preferably made of acrylic resin. With a liquid-phase method such as spin coating, it is possible to form the interlayer insulating film with highly accurate evenness. Furthermore, openings for forming the TFT coupling part 314 and the organic EL coupling part 315 are provided to the interlayer insulating film 316 by light exposure via a mask or photolithography.

Subsequently, the TFT coupling part 314 is provided by electroless plating. The TFT coupling part 314 is a bump.

First, in order to improve the wettability of a pad surface for plating growth and remove a residue thereon, they can be immersed in a water solution containing hydrofluoric acid and sulfuric acid. Next, they can be immersed in a heated alkaline water solution containing sodium hydroxide in order to remove an oxide film on the surface. They can then be immersed in a zincate solution containing ZnO in order to replace the pad surface with Zn. Then they are immersed in a nitric acid water solution to peel off Zn, and in a zincate bath again in order to precipitate fine Zn particles on the Al surface. Subsequently, openings are immersed in an electroless Ni plating bath in order to provide Ni plating. The plating is provided to a thickness of about 2 to 10 μm. Since the plating bath includes hypophosphorous acid as a reducer, phosphorous (P) is co-precipitated. Lastly, they are immersed in a substitution Au plating bath in order to replace the Ni surface with Au. Au plating is formed to a thickness of about 0.05 to 0.30 μm. A cyanide-free Au bath is used here.

This way an Ni—Au bump (TFT coupling part 14) is formed on the pad. Also, a solder or lead-free solder such as Sn—Ag—Cu can be deposited on the Ni—Au plating bump by screen printing or dipping.

Note that rinsing in water is performed between each chemical processing. A rinsing bath used here has an overflow structure or QDR mechanism, and provides N2 bubbling from the bottom. The bubbling is done with a Teflon (trademark registered) tube or the like provided with holes so as to supply N2 or with a sintered body through which N2 is supplied. Through the above process, rinsing is sufficiently effective in a short period of time.

Next, the organic EL coupling part 315 is provided. Any deposition technique can be used here. For example, vapor-phase methods used for semiconductor manufacturing processes such as CVD, sputtering, evaporation, and ion plating can be used. Alternatively, the organic EL coupling part 315 can be formed by a liquid-phase method. In this case, a dispersion liquid in which fine metallic particles are mixed with a solvent is used as a material liquid. Examples of the liquid-phase method may include spin coating, slit coating, dip coating, spray coating, roll coating, curtain coating, printing, and droplet discharge.

Through the series of steps, the wiring substrate 303 is manufactured.

Referring now to FIGS. 11 through 13, a method for joining the wiring substrate 303 and the base substrate 340 so as to transfer the TFT 313 to the wiring substrate 303 will be described.

Here, a known technique can be used for this transferring step. In the exemplary embodiment, Surface Free Technology by Laser Ablation (SUFTLA, trademark registered) is used, in particular.

As shown in FIG. 11, with the base substrate 340 inverted, the base substrate 340 and the wiring substrate 303 are joined by applying a conductive paste 317 containing anisotropic conductive particles (ACP) between the TFT 313 and the TFT coupling part 314.

As shown in FIG. 12, the part to which the conductive paste 317 is applied is locally irradiated with laser light LA from the back side of the base substrate 340 (the surface on which the TFT is not provided). Accordingly, the interatomic or intermolecular bonding force of the separating layer 341 are reduced, and hydrogen contained in the separating layer 341 forms molecules to be separated from crystal bonding. Therefore, the bonding force between the TFT 313 and the base substrate 340 is reduced to zero, which makes it possible to easily separate the TFT in the part irradiated with the laser light LA.

Next, by separating the base substrate 340 from the wiring substrate 303 as shown in FIG. 13, the TFT is removed from the upper surface of the base substrate 340, while the TFT 313 is transferred to the wiring substrate 303. Note that a terminal of the TFT 313 is coupled to the wiring pattern 311 with the TFT coupling part 314 and the conductive paste 317 therebetween.

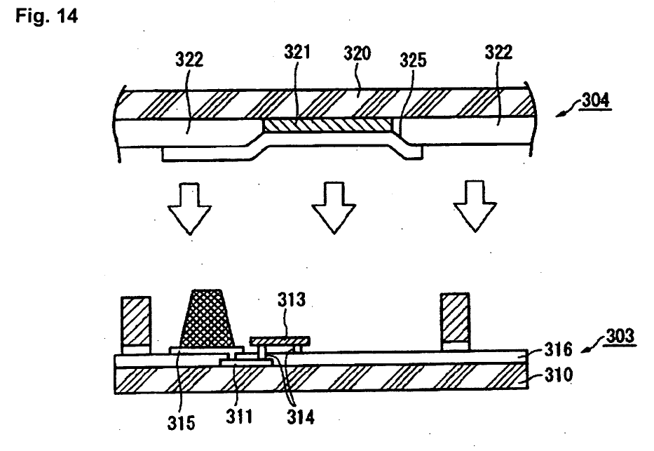

Referring now to FIG. 14, a step for joining the wiring substrate 303 and the organic EL substrate 304 so as to provide the organic EL device 301 shown in FIG. 7 will be described.

The organic EL substrate 304 shown in FIG. 14 includes the organic EL element 321, the insulating layer 322, and the cathode 325 that are provided on the transparent substrate 320 in this order and then put upside down. Here, the method illustrated in FIG. 2 is used for providing the organic EL element 321, the insulating layer 322, and the cathode 325 on the transparent substrate 320. In other words, the organic EL element 321, the insulating film 322, and the cathode 325 are provided by droplet discharge on the transparent substrate 320 that is a tape-like substrate.

The wiring substrate 303 is placed face to face with the organic EL substrate 304. With an adhesive applied on the upper surface of the rib 305, the two substrates 303 and 304 are joined together with pressure. Accordingly, the upper surface of the conductive part 330 comes in contact with the cathode 325, and thereby the conductive part 330 is pressed against the cathode 325. Thus, the organic EL coupling part 315 and the cathode 325 are electrically coupled with the conductive part 330 therebetween. In other words, the organic EL element 321 and the drive element 313 are electrically coupled with each other.

In this state, the inert gas 331 is filled in between the wiring substrate 303 and the organic EL substrate 304. By sealing the periphery of the both substrates 303 and 304 as shown in FIG. 7, the organic EL device 301 is completed.

Since the rib 305 has the through-hole 305a, the inert gas 331 flows into or out of an area next to the area 306 through the through-hole 305a. Accordingly, the inert gas 331 is included in the both substrates 303 and 304 with the same pressure.

To include the inactive gas 331 and sealing the substrates, the inactive gas is included after joining the wiring substrate 303 and the organic EL substrate 304 and then the substrates are sealed. Alternatively, the wiring substrate 303 and the organic EL substrate 304 are joined together in a chamber of an inactive gas atmosphere and then the substrates are sealed.

The organic EL device 301 shown in FIG. 7 made by the above-mentioned method and including the cathode 325, the organic EL element (luminescent layer), the hole injection/transport layer, and the anode on the organic EL substrate 304 from the wiring substrate 303 side, is a top-emission organic EL device that lets out light from the transparent substrate 320 side. The organic EL device 301 is an active organic EL device that includes the TFT 313 for each pixel.

According to the exemplary embodiment, the organic EL substrate 304 is provided by droplet discharge on the tape-like substrate 11 serving as a reel-to-reel substrate. The active organic EL device 301 is provided that includes the organic EL substrate 304. Therefore, it is possible to mass produce active organic EL devices economically and promptly according to the present embodiment.

(Electronic Equipment)

Electronic equipment manufactured by the above-described method or system for manufacturing an organic EL element will now be described.

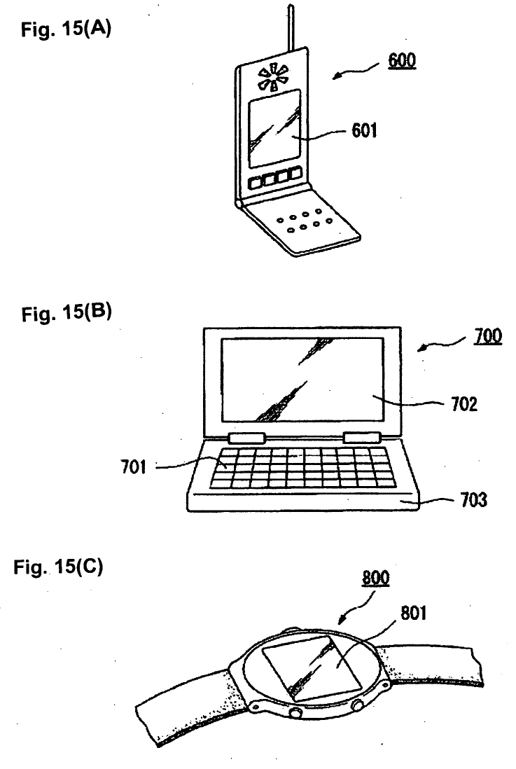

FIG. 15A is a perspective view showing an example of a cellular phone. Referring to FIG. 15A, a cellular phone body 600 includes a display 601 composed of an organic EL device manufactured by the above-described method or system for manufacturing an organic EL element. FIG. 15B is a perspective view illustrating an example of a portable information processor, such as word processors and personal computers. Referring to FIG. 15B, an information processor 700 includes an input unit 701, such as a keyboard, a display 702 composed of an organic EL device manufactured by the above-described method or system for manufacturing an organic EL element, and an information processor body 703. FIG. 15C is a perspective view illustrating an example of wristwatch electronic equipment. Referring to FIG. 15C, a wristwatch body 800 includes a display 801 composed of an organic EL device manufactured by the above-described method or system for manufacturing an organic EL element.

Since each of the electronic equipment shown in FIGS. 15A through 15C includes an organic EL device manufactured by the above-described method or system for manufacturing an organic EL element, it is possible to mass produce quality electronic equipment economically.

It should be understood that the technical scope of the present invention is not limited to the above embodiments, and various modifications can be applied to the invention without departing from the spirit and scope of the invention. The exemplary materials and layer structures are shown in the embodiments by way of example only, and modifications can be appropriately made thereto.

1. A method for manufacturing an organic electroluminescent element provided on a tape-like substrate, comprising:
providing the tape-like substrate, both ends of which are reeled in as a reel-to-reel substrate; and
providing a hole injection/transport layer that applies a liquid substance containing a component of the hole injection/transport layer of the organic electroluminescent element on the reel-to-reel substrate by at least using a droplet discharge method that discharges and applies the liquid substance as a droplet.

2. A method for manufacturing an organic electroluminescent element provided on a tape-like substrate, comprising:
providing the tape-like substrate, both ends of which are reeled in as a reel-to-reel substrate; and
providing a luminescent layer that applies a liquid substance containing a component of the luminescent layer of the organic electroluminescent element on the reel-to-reel substrate by at least using a droplet discharge method that discharges and applies the liquid substance as a droplet.

3. A method for manufacturing an organic electroluminescent element provided on a tape-like substrate, comprising:
at least providing a hole injection/transport layer that applies a liquid substance containing a component of the hole injection/transport layer of the organic electroluminescent element on a reel-to-reel substrate by at least using a droplet discharge method that discharges and applies the liquid substance as a droplet or providing a luminescent layer that applies a liquid substance containing a component of the luminescent layer of the organic electroluminescent element on the reel-to-reel substrate by at least using a droplet discharge method that discharges and applies the liquid substance as a droplet during a period beginning when the reel-to-reel substrate is pulled out to when the reel-to-reel substrate is reeled in; and
providing the hole injection/transport layer is followed by providing the luminescent layer.

4. A method for manufacturing an organic electroluminescent element provided on a tape-like substrate, comprising:
at least providing a hole injection/transport layer that applies a liquid substance containing a component of the hole injection/transport layer of the organic electroluminescent element on a reel-to-reel substrate by at least using a droplet discharge method that discharges and applies the liquid substance as a droplet or providing a luminescent layer that applies a liquid substance containing a component of the luminescent layer of the organic electroluminescent element on the reel-to-reel substrate by at least using a droplet discharge method that discharges and applies the liquid substance as a droplet during a period beginning when the reel-to-reel substrate is pulled out to when the reel-to-reel substrate is reeled in; and
providing the hole injection/transport layer and providing the luminescent layer being performed for the same reel-to-reel substrate in an overlapping time period.

5. The method for manufacturing an organic electroluminescent element according to claim 3, further comprising:
hardening a liquid substance applied on the reel-to-reel substrate by at least one of providing the hole injection/transport layer and providing the luminescent layer.

6. The method for manufacturing an organic electroluminescent element according to claim 5,
hardening being performed between providing the hole injection/transport layer and providing the luminescent layer.

7. The method for manufacturing an organic electroluminescent element according to claim 1, further comprising:
providing a drive element to a base substrate that is other than the tape-like substrate; and
joining the base substrate and one of the tape-like substrate and a substrate included in an organic electroluminescent device so as to transfer the drive element to one of the tape-like substrate and the substrate included in the organic electroluminescent device.

8. A system for manufacturing an organic electroluminescent element, comprising:
a first reel around which a tape-like substrate is wound;
a second reel that reels the tape-like substrate pulled out from the first reel;
a first droplet discharge device including a first discharge head that discharges a liquid substance containing a component of a hole injection/transport layer of the organic electroluminescent element as a droplet on the tape-like substrate pulled out from the first reel;
a second droplet discharge device including a second discharge head that discharges a liquid substance containing a component of a luminescent layer of the organic electroluminescent element as a droplet on the tape-like substrate pulled out from the first reel;
a first head moving mechanism that moves the first discharge head relative to the tape-like substrate pulled out from the first reel; and
a second head moving mechanism that moves the second discharge head relative to the tape-like substrate pulled out from the first reel.

9. The system for manufacturing an organic electroluminescent element according to claim 8,
the first discharge head and the second discharge head being disposed adjacent to the tape-like substrate pulled out from the first reel;
the first discharge head being disposed closer to the first reel than the second discharge head; and
a drying device that hardens a liquid substance applied on the reel-to-reel substrate being disposed between the first discharge head and the second discharge head.

10. Electronic equipment manufactured by using the method for manufacturing an organic electroluminescent element according to claim 1.

11. Electronic equipment, comprising:
a passive organic electroluminescent device manufactured by using the method for manufacturing an organic electroluminescent element according to claim 1.

12. Electronic equipment, comprising:
an active organic electroluminescent device manufactured by using the method for manufacturing an organic electroluminescent element according to claim 1.

13. The method for manufacturing an organic electroluminescent element according to claim 4, further comprising:
hardening a liquid substance applied on the reel-to-reel substrate by at least one of providing the hole injection/transport layer and providing the luminescent layer.

14. The method for manufacturing an organic electroluminescent element according to claim 2, further comprising:
providing a drive element to a base substrate that is other than the tape-like substrate; and
joining the base substrate and one of the tape-like substrate and a substrate included in an organic electroluminescent device so as to transfer the drive element to one of the tape-like substrate and the substrate included in the organic electroluminescent device.

15. Electronic equipment manufactured by using the system for manufacturing an organic electroluminescent element according to claim 8.

16. Electronic equipment, comprising:
a passive organic electroluminescent device manufactured by using the system for manufacturing an organic electroluminescent element according to claim 8.

17. Electronic equipment, comprising:
an active organic electroluminescent device manufactured by using the system for manufacturing an organic electroluminescent element according to claim 8.
